(19) United States
(12) Patent Application Publication
(10) Pub. No.: US 2017/0221855 A1
(43) Pub. Date: Aug. 3, 2017

(54) METAL PASTE AND USE THEREOF FOR THE CONNECTING OF COMPONENTS

(71) Applicant: Heraeus Deutschland GmbH & Co. KG, Hanau (DE)

(72) Inventor: Jens NACHREINER, Schlüchtern (DE)

(21) Appl. No.: 15/308,787

(22) PCT Filed: Apr. 20, 2015
(86) PCT No.: PCT/EP2015/058476

§ 371 Date: Nov. 3, 2016

(30) Foreign Application Priority Data
May 5, 2014 (EP) 14167030.7

(51) Int. Cl. H01L 23/00; B22F 1/00; H01B 1/02

(52) U.S. Cl. CPC H01L 24/83; H01L 24/29; H01B 1/023; H01B 1/026; B22F 1/0062; B22F 1/0055; H01L 2224/8384; H01L 2224/29138; H01L 2224/29124; H01L 2224/29163; B22F 7/08

(57) ABSTRACT

A metal paste contains (A) 75% to 90% by weight of at least one metal that is present in the form of particles comprising a coating that contains, at least one organic compound, (B) 0% to 12% by weight of at least one metal precursor, (C) 6% to 20% by weight of a mixture of at least two organic solvents, and (D) 0% to 10% by weight of at least one sintering aid. 30% to 60% by weight of the solvent mixture (C) consists of at least one 1-hydroxyalkane with 16-20 C-atoms that is non-substituted except for a methyl substitution on the penultimate C-atom.

### CROSS-REFERENCE TO RELATED APPLICATIONS

This application is a Section 371 of International Application No. PCT. EP2015/058476, filed Apr. 20, 2015, which was published in the German language on Nov. 12, 2015 under International Publication No. WO 2015/169571 A1 and the disclosure of which is incorporated herein by reference.

### BACKGROUND OF THE PRESENT INVENTION

The present invention relates to a metal sintering paste and to a method for the connecting of components in which the metal paste is used,

In power and consumer electronics, the connecting of components, such as LEDs or very thin silicon chips that are highly pressure and temperature sensitive, is particularly challenging.

For this reason, the pressure- and temperature-sensitive components are often connected to each other by means of gluing. However, adhesive technology is associated with a disadvantage in that it produces contact sites between the components that comprise only insufficient heat conductivity and/or electrical conductivity.

In order to solve this problem, the components to be connected are often subjected to sintering. Sintering technology is a very simple method for the connecting of components in stable manner.

However, conventional sintering processes require either a high process pressure and/or a high process temperature. These conditions often lead to damage to the components to be connected, such that conventional sintering processes are excluded for many applications.

It is known in power electronics to use metal pastes in a sintering process to connect components.

WO 2011/026623 A1 discloses a metal paste containing 75% to 90% by weight (percent by weight) of at least one metal that is present in the form of particles that comprise a coating that contains at least one organic compound, 0% to 12% by weight of at least one metal precursor, 6% to 20% by weight of at least one solvent, and 0.1% to 15% by weight of at least one sintering aid, as well as the use of the metal paste to connect components by means of a sintering method.

### BRIEF SUMMARY OF THE PRESENT INVENTION

It is an objective of the present invention to provide a sintering method for connecting components in stable manner that can be performed in the absence of pressure even at temperatures of, for example, 200° C. to 250° C. The method may be used to produce contact sites of low porosity and high electrical and thermal conductivity between the components to be connected. It is another objective of the present invention to provide a metal paste that is adapted for implementing a sintering method of this type.

### DETAILED DESCRIPTION OF THE PRESENT INVENTION

The present invention relates to a method for the connecting of components comprising (a) providing a sandwich arrangement that contains at least (a1) one component 1, (a2) one component 2, and (a3) one metal paste that is situated between component 1 and component 2, and (b) sintering the sandwich arrangement, wherein the metal paste comprises (A) 75% to 90% by weight of at least one metal that is present in the form of particles comprising a coating that contains at least one organic compound, (B) 0% to 12% by weight of at least one metal precursor, (C) 6% to 20% by weight of a mixture of at least two organic solvents, and (D) 0% to 10% by weight of at least one sintering aid, 30% to 60% by weight of the solvent mixture (C) consists of at least one 1-hydroxyalkane with 16-20 C-atoms that is non-substituted except for a methyl substitution on the penultimate C-atom.

The present invention also relates to a metal paste that contains (A) 75% to 90% by weight of at least one metal that is present in the form of particles comprising a coating that contains at least one organic compound, (B) 0% to 12% by weight of at least one metal precursor, (C) 6% to 20% by weight of a mixture of at least two organic solvents, and (D) 0% to 10% by weight of at least one sintering aid. 30% to 60% by weight of the solvent mixture (C) consists of at least one 1-hydroxyalkane with 16-20 C-atoms that is anon-substituted except for a methyl substitution on the penultimate C-atom.

The metal paste according to the present invention contains 75% to 90% by weight, preferably 77% to 89% by weight, more preferably 78% to 87% by weight, and even more preferably erably 78% to 86% by weight, of at least one metal that is present in the form of particles comprising as coating that contains at least one organic compound. The weights given presently include the weight of the coating compounds situated on the particles.

The term “metal” shall include both pure metals and metal alloys.

In the scope of the present invention, the term “metal” refers to elements in the periodic system of the elements that are in the same period as boron, but to the left of boron, in the same period as silicon, but to the left of silicon, in the same period as germanium, but to the left of germanium, and in the same period as antimony, but to the left of antimony, as well as all elements having an atomic number of more than 55.

In the scope of the present invention, pure metals shall be understood to be metals containing a metal at a purity of at least 95%, by weight, preferably at least 98% by weight, more preferably at least 99% by weight, and even more preferably at least 99.9% by weight.

According to a preferred embodiment, the metal is copper, silver, gold, nickel, palladium, platinum or aluminium, in particular silver.

Metal alloys shall be understood to be metallic mixtures of at least two components of which at least one is a metal.

According to a preferred embodiment, an ahoy containing copper, aluminum, nickel and/or precious metals is used as metal alloy. The metal alloy preferably comprises at least one metal selected from the group consisting of copper, silver, gold, nickel, palladium, platinum, and aluminum. Particularly preferred metal alloys contain at least two metals selected from the group consisting of copper, silver, gold, nickel, palladium, platinum, and aluminum. Moreover, it can be preferred that the fraction of metals selected from the group consisting of copper, silver, gold, nickel, palladium, platinum, and aluminum accounts for at least 90% by weight, preferably at least 95% by weight, more preferably at least 99% by weight, and even more preferably 100% by weight of the metal alloy. The alloy can, for example, be an alloy that contains copper and silver, copper, silver and gold, copper and gold, silver and gold, silver and palladium, platinum and palladium or nickel and palladium.

The metal paste according to the present invention can contain, as metal, a pure metal, multiple types of pure metal, a type of metal alloy, multiple types of metal alloys or mixtures thereof.

The metal is present in the metal paste in the form of particles.

The metal particles can differ in shape. The metal particles can be present, for example, in the form of flakes or be of a spherical (ball-like) shape. According to a particularly preferred embodiment, the metal particles take the shape of flakes. However, this does not exclude a minor fraction of the particles employed being of a different shape. However, preferably at least 70% by weight, more preferably at least 80% by weight, even more preferably at least 90% by weight or 100% by weight, of the particles are present in the form of flakes.

The metal particles are coated.

The term, coating of particles, shall be understood to refer to a firmly adhering layer on the surface of particles.

The coating of the metal particles contains at least one type of coating compound.

The coating compounds are organic compounds.

The organic compounds serving as coating compounds are carbon-containing compounds that prevent the metal particles from agglomerating.

According to a preferred embodiment, the coating compounds bear at least one functional group. Conceivable functional groups include, in particular, carboxylic acid groups, carboxylate groups, ester groups, keto groups, aldehyde groups, amino groups, amide groups, azo groups, imide groups or nitrite groups. Carboxylic acid groups and carboxylic acid ester groups are preferred functional groups. The carboxylic acid group can be deprotonated.

The coating compounds with at least one functional group preferably are saturated, mono-unsaturated or multi-unsaturated organic compounds.

Moreover, the coating compounds with at least one functional group can be branched or non-branched.

The coating compounds with at least one functional group preferably comprise 1 to 50, More preferably 2 to 24, even more preferably 6 to 24, and yet more preferably 8 to 20 carbon atoms.

The coating compounds can be ionic or non-ionic.

It is preferable to use free fatty acids, fatty acid salts or fatty acid esters as the coating compounds.

The free fatty acids, fatty acid salts, and fatty acid esters preferably ate non-branched.

Moreover, the free fatty acids, fatty acid salts, and fatty acid esters preferably are saturated.

Preferred fatty acid salts include the ammonium, monoalkylammonium, dialkylammonium, trialkylammonium, aluminium, copper, lithium, sodium, and potassium salts.

Alkyl esters, in particular methyl esters, ethyl esters, propyl esters, and butyl esters, are preferred esters.

According to a preferred embodiment, the free fatty acids, fatty acid salts or fatty acid esters are compounds with 8 to 24, more preferably 10 to 24, and even more preferably 12 to 18 carbon atoms.

Preferred coating compounds include caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), archinic acid (eicosanoic acid/icosanoic acid), behenic acid (docosanoic acid), lignoceric acid (tetracosanoic acid) as well as the corresponding esters and salts.

Particularly preferred coating compounds include dodecanoic acid, octadecanoic acid, aluminium stearate, copper stearate, sodium stearate, potassium stearate, sodium palmitate, and potassium palmitate.

The coating compounds can be applied to the surface of the metal particles by means of conventional methods that are known from the prior art.

It is possible, for example, to slurry the coating compounds, in particular the stearates or palmitates mentioned above, in solvents and to triturate the slurried coating compounds together with the metal particles in ball mills. After trituration, the metal particles, which are coated with the coating compounds, are dried and then dust is removed.

Preferably, the fraction of organic compounds, in particular the fraction of compounds selected from the group consisting of free fatty acids, fatty acid salts or fatty acid esters with 8 to 24, more preferably 10 to 24, and even more preferably 12 to 18 carbon atoms, of the entire coating is at least 60% by weight, more preferably at least 70%, even more preferably at least 80% by, yet more preferably at least 90% by weight, in particular at least 95% by weight, at least 99% by weight or 100% by weight.

Usually, the fraction of the coating compounds, preferably of the coating compounds selected from the group consisting of free fatty acids, fatty acid salts or fatty acid esters with 8 to 24, more preferably 10 to 24, and even more preferably 12 to 18 carbon atoms, is 0.01 to 2% by weight, preferably 0.3 to 1.5% by weight, with respect to the weight of the coated metal particles.

The degree of coating, defined as the ratio of the mass of coating compounds and the surface of the metal particles, preferably is 0.00005 to 0.03 g, more preferably 0.0001 to 0.02 g of coating compounds per square metre (m²) of surface area of the metal particles.

The metal paste according to the present invention contains 0 to by weight, preferably 0.1 to 12% by weight, more preferably 1 to 10% by weight, and even more preferably 2 to 8% by weight of at least one metal precursor.

In the scope of the present inveotion, a metal precursor shall be understood to mean a compound that contains at least one metal. Preferably, the compound decomposes at temperatures below 200° C. while releasing a metal. Accordingly, the use of a metal precursor in the sintering process is preferably associated with the in situ production of a metal. It is easy to determine whether a compound is a metal precursor. For example, a paste containing a compound to be tested can be deposited on a substrate having a silver surface followed by heating to 200° C., and maintaining this temperature for 20 minutes. Then, the paste is tested whether or not the compound to be tested decomposed under these conditions. For this purpose, for example, the content of the metal-containing paste components can be weighed before the test to calculate the theoretical mass of metal. After the test, the mass of the material deposited on the substrate is determined by gravimetric methods. If the mass of the material deposited on the substrate is equal to the theoretical mass of metal, taking into account the usual measuring inaccuracy, the tested compound is a metal precursor.

According to a preferred embodiment, the metal precursor is a metal precursor that can be decomposed endothermically. A metal precursor that can be decomposed endothermically shall be understood to be a metal precursor whose thermal decomposition, preferably in a protective gas atmosphere, is an endothermic process. The thermal decomposition is to be associated with the release of metal from the metal precursor.

According to another preferred embodiment, the metal precursor comprises a metal that is also present in the particulate metal (A).

The metal precursor preferably comprises, as metal, at least one element selected from the group consisting of copper, silver, gold, nickel, palladium, and platinum.

It can be preferred to use, as metal precursor, endothermically decomposable carbonates, lactates, formates, citrates, oxides or fatty acid salts, preferably fatty acid salts having 6 to 24 carbon atoms, of the metals specified above.

In specific embodiments, silver carbonate, silver(I) lactate, silver(II) formate, silver citrate, silver oxide (for example AgO or Ag₂O), copper(II) lactate, copper stearate, copper oxides (for example Cu₂O or CuO) Or gold oxides (for example Au₂O or AuO) are used as the metal precursor.

According to a particularly preferred embodiment, silver carbonate, silver(I) oxide or silver(II) oxide is used as the metal precursor.

The metal precursor, if present in the metal paste, is preferably present in the form of particles.

The metal precursor particles can take the shape of flakes or a spherical (ball-like) shape. Preferably, the metal precursor particles are present in the form of flakes.

The metal paste according to the present invention contains 6 to 20% by weight, preferably 7 to 18% by weight, more preferably to by weight, and even more preferably 10 to 15% by weight, of a mixture of at least two organic solvents, of which 30 to 60% by weight, preferably 30 to 50% by weight, consist of at least one 1-hydroxyalkane with 16-20 C-atoms that is non-substituted except for a methyl substitution on the penultimate c-atom.

1-hydroxyalkanes with 16-20 C-atoms that are non-substituted except for a methyl substitution on the penultimate C-atom include: 14-methylpentadecan-1-ol, 15-methylhexadecan-1-ol, 16-methylheptadecan-1-ol, 17-methyloctadecan-1-ol, and 18-methylnonadecan-1-ol. 16-Methylheptadecan-1-ol is preferred and is commercially available by the name of isooctadecanol.

Preferably, the mixture of the at least two organic solvents contains just 16-methylheptadecan-1-ol as 1-hydroxyalkane with 16-20 C-atoms that is non-substituted except for a methyl substitution on the penultimate C-atom.

Aside from the 30 to 60% by weight, preferably 30 to 50% by weight, of at least one 1-hydroxyalkane with 16-20 C-atoms that is non-substituted except for a methyl substitution on the penultimate C-atom, the mixture of the at least two organic solvents correspondingly contains 40 to 70% by weight, preferably 50 to 70% by weight (i.e. the weight fraction needed to add up to 100% by weight) of at least one further organic solvent; i.e., of at least one organic solvent that is different from the 1-hydroxyalkane with 16-20 C-atoms that is non-substituted except for a methyl substitution on the penultimate C-atom. This includes organic solvents that are commonly used for metal pastes. Examples include terpineols, N-methyl-2-pyrrolidone, ethylene glycol, dimethylacetamide, 1-tridecanol, 2-tridecanol, 3-tridecanol, 4-tridecanol, 5-tridecanol, 6-tridecanol, isotridecanol dibasic esters (preferably dimethylesters of ghttaric, adipic or succinic acid or mixtures thereof), glycerol, diethylene glycol, triethylene glycol, and aliphatic hydrocarbons, in particular saturated aliphatic hydrocarbons, with A5 to 32 C-atoms, more preferably 10 to 25 C-atoms, and even more preferably 16 to 20 C-atoms. The aliphatic hydrocarbons are being marketed, for example, by Exxon Mobil by the brand name Exxsol D140 or by the brand name Isopar M.

Preferably, the mixture of at least two organic solvents consists of 30 to 60% by weight, preferably 30 to 50% by weight, 16-methylheptadecan-1-ol and 40 to 70% by weight, preferably 50 to 70% by weight, of at least one organic solvent selected from 1-tridecanol, terpineols, and saturated aliphatic hydrocarbons with 16 to 20 C-atoms, wherein the specified % by weight at up to 100% by weight.

In one specific embodiment, the at least one 1-hydroxy-C16-C20-alkane that is non-substituted except for a methyl substitution on the penultimate C-atom and is present in the metal paste according to the present invention, and the at least one coating compound that is also present in the metal paste according to the present invention and has been explained in the context of metal component (A) differ by not more than two, preferably by not more than one, particularly preferably not at all, in the number of their C-atoms. In other words, if the metal paste according to the present invention contains free fatty acids, fatty acid salts or fatty acid esters as one or more of the coating compounds of the metal particles of component (A), then the 1-hydroxy-C16-C20-alkane that is non-substituted except for a methyl substitution on the penultimate C-atom and is present in the metal paste according to the present invention and the fatty acid(s), fatty acid salt(s) or fatty acid ester differ by not more than two, preferably by not more than one, particularly preferably not at all, in the number of their C-atoms.

The metal paste according to the present invention contains 0 to 10% by weight, preferably 0 to 8% by weight, of at least one sintering aid. Examples of sintering aids include organic peroxides, inorganic peroxides, and inorganic acids, such as are described, for example, in WO 2011/026623 A1.

The metal paste according to the present invention can contain 0 to 15% by weight, preferably o to 12% by weight, more preferably 0.1 to 10% by weight, of one or more further ingredients (E) aside from ingredients (A) to (D) described above. The farther ingredients can preferably be ingredients that are used commonly in metal pastes. The metal paste can contain, for example, as further ingredients, dispersion agents surfactants, de-foaming agents, binding agents, polymers such as cellulose derivatives, for example methylcellulose ethylcellulose, ethylmethylcellulose, carboxycellulose, hydroxypropylcellulose, hydroxyethylcellulose, hydroxymethylcellulose and/or viscosity-controlling (rheological) agents.

The sum of the % by weight fractions specified for ingredients (A) to (E) adds up, for example, to 100% by weight with respect to the metal paste according to the present invention (i.e., prior to the application thereof). Accordingly, the metal paste according to the present invention can be produced by mixing ingredients (A) to (E). Devices known to a person skilled in the art, such as stiffen and three-roller mills, can be used in this context.

The metal paste according to the present invention can be used as sintering paste (i.e., in a sintering process). Sintering shall be understood to mean the connecting of two or more components by heating without the metal particles reaching the liquid phase.

The sintering method implemented through the use of the metal paste according to the present invention can be implemented while applying pressure or, as an advantage of the present invention, without pressure. Being able to implement the sintering method without pressure means that a sufficiently firm connection of components is attained despite foregoing the application of pressure. Being able to implement the sintering process without pressure allows pressure-sensitive, for example fragile components or components with a mechanically sensitive micro-structure, to be used in the sintering method Electronic components that have a mechanically sensitive micro-structure suffer electrical malfunction when exposed to inadmissible pressure.

Connecting at least two components shall be understood to mean attaching a first component on a second component. In this context, “on” simply means that a surface of the first component is being connected to a surface of the second component regardless of the relative disposition of the two components or of the arrangement containing the at least two components.

In the scope of the present invention, the term “component” preferably comprises single parts. Preferably, the single parts cannot be disassembled further.

According to specific embodiments, the term “components” refers to parts that are used in electronics.

Accordingly, components can, for example, be diodes, LEDs (light-emitting diodes, lichtemittierende Dioden), DCB (direct copper bonded) substrates, lead frames, dies, IGBTs (insulated-gate bipolar transistors, Bipolartransistoren mit isoherter Gate-Elektrode), ICs (integrated circuits, integrierte Schaltungen), sensors heat sink elements (preferably aluminium heat sink elements or copper heat sink elements) or other passive components (for example, resistors, capacitors or coils).

The components to be connected can be identical or different components.

Preferred embodiments of the present invention relate to the connecting of LED to lead frame, LED to ceramic substrate, of dies, diodes, IGBTs or ICs to lead frames, ceramic substrates or DCB substrates, of sensor to lead frame or ceramic substrate. The connection can involve, for example, copper or silver contact surfaces of the electronics components to copper or silver contact surfaces of the substrates. That is, for example, a copper-silver, copper-copper, silver-copper or silver-silver connection can be formed.

As described in the preceding section, the components can comprise at least one metallization layer. The metallization layer preferably is part of the component. Preferably, the metallization layer is situated at at least one surface of the component,

Preferably, the connecting of the components by means of the metal paste according to the present invention is effected by means of the metallization layer or layers.

The metallization layer can comprise pure metal. Accordingly, it is preferable for the metallization layer to comprise at least 50% by weight, more preferably at least 70% by weight, even more preferably at least 90% by weight or 100% by weight of pure metal. Preferably, the pure metal is selected from the group consisting of copper, silver, gold, palladium, and platinum.

On the other hand, the metallization layer can just as well comprise an alloy. The alloy of the metallization layer preferably contains at least one metal selected from the group consisting of silver, copper, gold, nickel, palladium, and platinum. It can be preferred just as well that at least two metals selected from the group consisting of silver, copper, gold, nickel, palladium, and platinum are present in the alloy of the metallization layer.

The metallization layer can just as well have a multi-layer structure. Accordingly, it is preferable that at least one surface of the components to be connected comprises a metallization layer made of multiple layers that comprise the pure metals and/or alloys specified above.

In the method according to the present invention, at least two components are being connected to each other through sintering.

For this purpose, the two components are first made to contact each other. The contacting is effected by means of the metal paste according to the present invention in this context. For this purpose, an arrangement is provided, in which metal paste according to the present invention is situated between each two of the at least two components.

Accordingly, if two components, i.e., component 1 and component 2, are to be connected to each ether, the metal paste according to the present invention is situated between component 1 and component 2 before the sintering process. On the other band, it is conceivable to connect more than two components to each other. For example three components, i.e. component 1, component 2, and component 3, can be connected to each other in appropriate manner such that component 2 is situated between component 1 and component 3. In this case, the metal paste according to the present invention is situated both between component 1 and component 2 as well as between component 2 and component 3.

The individual components are present in a sandwich arrangement and are being connected to each other. Sandwich arrangement shall be understood to mean an arrangement, in which two components are situated one above the other with the two components being arranged essentially parallel with respect to each other.

The arrangement of at least two components and metal paste according to the present invention, wherein the metal paste is situated between two components of the arrangement, can be produced according to any method known according to the prior art.

Preferably, firstly, at least one surface of a component 1 is provided with the metal paste according to the present invention. Then, another component 2 is placed by one of its surfaces on the metal paste that has been applied to the surface of component 1.

The application of the metal paste according to the present invention onto the surface of the component: can take place by means of conventional processes, for example by means of printing processes such as screen printing or stencil printing. On the other hand, the metal paste according to the present invention can be applied just as well by dispensing technique, by means of pin transfer or by dipping.

Following the application of the metal paste according to the present invention, it is preferable to contact the surface of the component that has been provided with the metal paste to a surface of the component to be connected thereto by means of the metal paste. Accordingly, as layer of the metal paste according to the present invention is situated between the components to be connected.

Preferably, the thickness of the wet layer between the components to be connected is in the range of 20 to 100 μm. In this context, thickness of the wet layer shall be understood to mean the distance between the opposite surfaces of the components to be connected prior to drying, if any, and prior to sintering. The preferred thickness of the wet layer depends on the method selected for applying the metal paste. If the metal paste is applied, for example, by means of a screen priming method, the thickness of the wet layer can preferably be 20 to 50 μm. If the metal paste is applied by means of stencil priming, the preferred thickness of the wet layer can be in the range of 20 to 100 μm. The preferred thickness of the wet layer in the dispensing technique can be in the range of 20 to 100 μm.

As an option, a drying step is introduced prior to the sintering (i.e., the organic solvent is removed from the applied metal paste). According to a preferred embodiment, the fraction of organic solvent in, the metal paste after drying is, for example, 0% to 5% by weight with respect to the original fraction sl organic solvent in the metal paste according to the present inention (i.e., in the metal paste ready for application). In other words, according to the preferred embodiment, for example 95% to 100% by weight of the organic solvent that is originally present in the metal paste according, to the present invention are removed during drying.

If drying takes place in a sintering process without pressure, the drying can proceed after producing the arrangement (i.e., after contacting the components to be connected). If drying takes place in a sintering process involving the application of pressure, the drying can just as well proceed after application of the metal paste onto the at least one surface of the component and before contacting to the component to be connected.

Preferably, the drying temperature is in the range of 100° C. to 150° C.

Obviously, the drying time depends on the composition of the metal paste according to the present invention and on the size of the connecting surface of the arrangement to be sintered. Common drying times are in the range of 5 to 45 minutes.

The arrangement consisting of the at least two components and metal paste situated between the components is finally subjected to a sintering process.

The actual sintering takes place at a temperature of, for example, 200° C. to 250° C.

The process pressure in pressure sintering is preferably less than 30 MPa and more preferably less than 5 MPa. For example, the process pressure is in the range of 1 to 30 MPa and more preferably is m the range of 1 to 5 MPa. As mentioned above, the particular advantage of the present invention is that the metal paste according to the present invention allows the sintering process to be performed without applying pressure yet still provide a sufficiently firm connection between components. Sintering without pressure is recommended whenever at least one of the components is pressure-sensitive, for example is fragile or its structure is mechanically sensitive.

The sintering time is, for example, in the range of 2 to 60 minutes. For example, the sintering time is in the range of 2 to 5 minutes in pressure sintering. For example, the sintering time is in the range of 30 to 60 minutes in sintering without pressure.

The sintering process can take place in an atmosphere that is not subject to an specific limitations. Accordingly, on the one hand, the sintering can take place in an atmosphere that contains oxygen. On the other hand, it is feasible just as well that the sintering takes place in an oxygen-free atmosphere. In the scope of the present invention, an oxygen-free atmosphere shall be understood to mean an atmosphere whose oxygen content is no more than 10 ppm, preferably no more than 1 ppm, and even more preferably no more than 0.1 ppm.

The sintering takes place in a conventional suitable apparatus for sintering, in which the above-mentioned process parameters can be set.

The present invention is illustrated through the following examples, though these may not he construed such as to karats the present invention in any way or form.

### EXAMPLES

### 1. Production of Metal Pastes:

Firstly, metal pastes 1 to 2 according to the present invention and reference pastes 3 to 7 were produced by mixing the individual ingredients according to the following Table 1. All amounts given are in units of % by weight.

TABLE 1

| | Paste 1 | Paste 2 | Paste 3 | Paste 4 | Paste 5 | Paste 6 | Paste 7 |
|---|---|---|---|---|---|---|---|
| Silver particles ¹⁾ | 83 | | 83 | | | | |
| Silver particles ²⁾ | | 85 | | 85 | 84 | 84 | 84 |
| Silver carbonate | 4.9 | 4.9 | 4.9 | 4.9 | 4.9 | 4.9 | 4.9 |
| 16- | 5 | 5 | | | | | |
| Methylheptadecan- | | | | | | | |
| 1-ol | | | | | | | |
| n-Heptadecanol | | | | | 5 | | |
| n-Octadecanol | | | | | | 5 | |
| n-Eicosanol | | | | | | | 5 |
| Tridecanol | 7.1 | 5.1 | 5.6 | 7.4 | 6.1 | 6.1 | 6.1 |
| Exxsol ™ D140 | | | 6.5 | 2.7 | | | |
| Total | 100 | 100 | 100 | 100 | 100 | 100 | 100 |

¹⁾ Silver flakes having a mean particle diameter (d50) of 3 μm and a coating of 1.5% by weight stearic acid
²⁾ Silver flakes having a mean particle diameter (d50) of 3 μm and a coating of 1.5% by weight lauric acid

### 2. Application and Pressure-Free Sintering of the Metal Pastes:

The specific metal paste was applied by dispensing onto the surface of a silver lead-frame at a weight layer thickness of 50 μm. Then, the applied metal paste was contacted without prior drying to a silicon chip having a silver contact surface (4·6 mm²). The following, heating profile was used in the subsequent pressure-free sintering: The contact site was heated steadily to 160° C. over the course of 60 minutes and then maintained at 160° C. for 30 minutes. Subsequently, the temperature was raised steadily to 230° C. over the course of 5 minutes and then maintained at this level for 60 minutes. Then, this was cooled steadily to 30° C. over the course of 50 minutes.

After the sintering, the bonding was determined by testing the shear strength. In this context, the components were sheared off with a shearing chisel at a rate of 0.3 at 20° C. The force was measured by means of a load cell (DAGE 2000 device made by DAGE, Germany).

Table 2 shows the results obtained with metal pastes 1 to 7.

TABLE 2

| | Paste | | | | | | |
|---|---|---|---|---|---|---|---|
| | 1 | 2 | 3 | 4 | 5 | 6 | 7 |
| Shear strength | 8.4 | 6.8 | 7.3 | 4.9 | 5.2 | 5.9 | 5.6 |
| (N/mm²) | | | | | | | |

It will be appreciated those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-11. (canceled)

12. A metal paste comprising:
(A) 75% to 90% by weight of at least one metal that is present in the form of particles comprising a coating that contains at least one organic compound;
(B) 0% to 12% by weight of at least one metal precursor;
(C) 6% to 20% by weight of a mixture of at least two, organic solvents; and
(D) 0% to 10% by weight of at least one sintering aid,
wherein 30% to 60% by weight of the solvent mixture (C) consists of at least one 1-hydroxyalkane with 16-20 C-atoms that is non-substituted except for a methyl substitution on the penultimate C-atom.

13. Metal paste according to claim 12, wherein the at least one metal is selected from the group consisting of copper, silver, gold, nickel, palladium, platinum, and aluminium.

14. Metal paste according to claim 12, wherein the metal particles are in the shape of flakes.

15. Metal paste according to claim 12, wherein the at least one organic compound is selected from the group consisting of free fatty acids, fatty acid salts, and fatty acid esters.

16. Metal paste according to claim 12, wherein the at least one 1-hydroxyalkane and the at least one organic compound differ by not more than two in the number of their C-atoms.

17. Metal paste according to claim 12, wherein the at least one 1-hydroxyalkane comprises 16-methylheptadecan-1-ol.

18. Metal paste according to claim 17, wherein the at least one 1-hydroxyalkane is 16-methylheptadecan-1-ol.

19. Metal paste according to claim 12, further comprising, aside from ingredients (A) to (D) 0% to 15% by weight of one or more further ingredients (E) selected from the group consisting of dispersion agents, surfactants, de-foaming agents, binding agents, polymers and viscosity-controlling agents.

20. Method for the connecting of components comprising:
(a) providing a sandwich arrangement that comprises at least a first component (a1), a second component (a2), and one metal paste (a3) according to claim 12 that is situated between the first and second components; and
(b) sintering the sandwich arrangement.

21. Method according to claim 20, wherein the sintering takes place with or without pressure.

22. Method according to claim 20, wherein the first and second components are parts that are used in electronics.
